(19) United States
(12) Patent Application Publication
(10) Pub. No.: US 2013/0113561 A1
(43) Pub. Date: May 9, 2013

(54) OUTPUT MODE SWITCHING AMPLIFIER

(71) Applicants: Kenichi Horiguchi, Tokyo (JP); Naoko Matsunaga, Tokyo (JP); Hiroshi Otsuka, Tokyo (JP); Masatoshi Nakayama, Tokyo (JP); Kazuhiro Iyomasa, Tokyo (JP); Akira Inoue, Tokyo (JP)

(72) Inventors: Kenichi Horiguchi, Tokyo (JP); Naoko Matsunaga, Tokyo (JP); Hiroshi Otsuka, Tokyo (JP); Masatoshi Nakayama, Tokyo (JP); Kazuhiro Iyomasa, Tokyo (JP); Akira Inoue, Tokyo (JP)

(73) Assignee: MITSUBISHI ELECTRIC CORPORATION, TOKYO (JP)

(21) Appl. No.: 13/810,388

(22) PCT Filed: Oct. 21, 2010
(86) PCT No.: PCT/JP2010/068575

§ 371 Date: Jan. 15, 2013

(51) Int. Cl. H03F 3/04

(52) U.S. Cl. CPC H03F 3/04
USPC 330/251

(57) ABSTRACT

An output mode switching amplifier, including: a transistor for signal amplification connected between a first node on an input side and a second node on an output side; a bypass path for bypassing the transistor between the first node and the second node; a voltage control circuit for switching whether to apply a bias voltage to the transistor so that a transmission signal is amplified by the transistor or to output a transmission signal via the bypass path without amplifying the transmission signal by the transistor; and a second-harmonic reflection circuit connected to the bypass path, for reflecting a second harmonic of the transmission signal.

### TECHNICAL FIELD

The present invention relates to an output mode switching amplifier for switching between a high output mode and a low output mode.

### BACKGROUND ART

Mobile phone terminals, for which downsizing and extended talk time are strongly demanded, are required to have lower power consumption of a power amplifier. In general, the amplifier has higher efficiency as the amplifier approaches saturation, and has low efficiency in the low output state apart from the saturation. Therefore, in view of battery-downsizing and talk time, the amplifier is desired to be used under the state as close to saturation as possible, having high efficiency.

Mobile phones radiate large power to an air space from an antenna when the distance from the terminal to a base station is long, and the radiated power from the antenna becomes smaller when the distance from the terminal to the base station becomes shorter. Therefore, the size of the amplifier is generally determined in preparation for maximum radiated power from the antenna. Thus, when the terminal is used near the base station, the amplifier operates in the low output state apart from the saturation, leading to a problem in that the efficiency is lowered.

To deal with this problem, a method of providing a bypass path so as to bypass a transistor when the output is low has been proposed (Patent Literature 1 below). In this amplifier, an input signal is amplified by the transistor when the output is high (amplifying mode), but a signal is output while bypassing the transistor by the bypass path connected in parallel to the transistor when the output is low (bypass mode). At high output, such a voltage that the signal can be amplified by the transistor is applied to the transistor from a voltage control circuit. At low output, such a voltage that the transistor becomes the OFF state so as not to amplify the signal is applied to the transistor from the voltage control circuit. In this manner, the amplifying mode and the bypass mode are switched. Therefore, in this amplifier, the transistor is set to the OFF state to bypass the signal in the low output mode where the efficiency is generally lowered, and hence power consumption at low output can be reduced.

### CITATION LIST

### Patent Literature

[PTL 1] JP 2005-244862 A

### SUMMARY OF INVENTION

### Technical Problem

In the conventional output mode switching amplifier, impedance matching of the transistor for a transmission signal frequency (fundamental frequency) is performed with the use of matching circuits provided on the input and output sides of the transistor and in the bypass path. However, impedance matching for a second harmonic of the transmission signal is not performed, or the second-harmonic impedance matching is performed by sharing a combination of parameters of the matching circuits used for the fundamental-frequency impedance matching. It is therefore difficult to independently set the matching for the fundamental-frequency impedance and the matching for the second-harmonic impedance, and difficult to set both the matching for the fundamental-frequency impedance and the matching for the second-harmonic impedance to optimal values, resulting in a problem in that the efficiency of the amplifier is lowered.

It is an object of the present invention to provide an output mode switching amplifier having an improved amplifier efficiency, in which matching for fundamental-frequency impedance and matching for second-harmonic impedance can be set to optimum states.

### Solution to Problem

The present invention provides an output mode switching amplifier, including: a transistor for signal amplification connected between a first node on an input side and a second node on an output side; a bypass path for bypassing the transistor between the first node and the second node; a voltage control circuit for switching whether to apply a bias voltage to the transistor so that a transmission signal is amplified by the transistor or to output a transmission signal via the bypass path without amplifying the transmission signal by the transistor; and a second-harmonic reflection circuit connected to the bypass path, for reflecting a second harmonic of the transmission signal.

### Advantageous Effects of Invention

According to the present invention, it is possible to provide the output mode switching amplifier having an improved amplifier efficiency, in which matching for fundamental-frequency impedance and matching for second-harmonic impedance can be set to optimum states.

### BRIEF DESCRIPTION OF DRAWINGS

FIG. 1A configuration diagram illustrating an output mode switching amplifier according to a first embodiment of the present invention.

FIG. 2 A configuration diagram illustrating an output mode switching amplifier according to a second embodiment of the present invention.

### DESCRIPTION OF EMBODIMENTS

Referring to the drawings, an output mode switching amplifier according to the present invention is described below by way of embodiments. Note that, in the embodiments, the same or corresponding parts are denoted by the same reference symbols, and their repetitive descriptions are omitted.

### First Embodiment

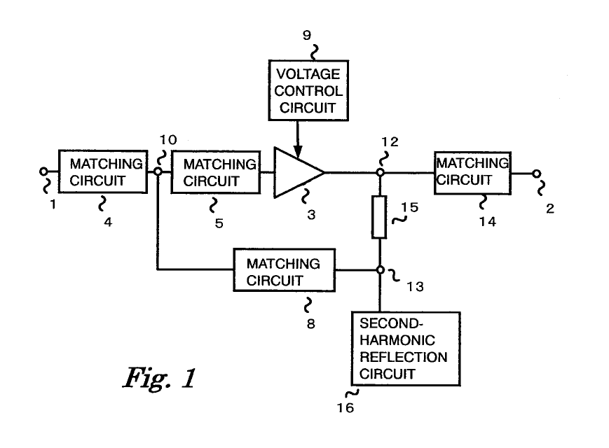

FIG. 1 is a configuration diagram of an output mode switching amplifier according to a first embodiment of the present invention. In FIG. 1, a transistor 3 for signal amplification and a series circuit of a matching circuit 8 and a microstrip line 15, the series circuit constituting a bypass path, are connected in parallel between a first node 10 on the input side and a second node 12 on the output side. A second-harmonic reflection circuit 16 is connected to a third node 13, which is a connection point between the matching circuit 8 and the microstrip line 15 in the bypass path. Ahead of the second-harmonic reflection circuit 16 is a power supply terminal.

Matching circuits 4, 5, and 14 are connected in series respectively between an RF input terminal 1 serving as an amplifier input and the first node 10, between the first node 10 and the transistor 3, and between the second node 12 and an RF output terminal 2 serving as an amplifier output. A voltage control circuit 9 supplies bias voltages to the transistor 5 and each switch described later to control and switch the operation.

In the amplifier of FIG. 1, an input signal is amplified by the transistor 3 when the output is high (amplifying mode), but a signal is output while bypassing the transistor 3 by the bypass path when the output is low (bypass mode). In the amplifying mode, such a bias voltage that the signal can be amplified by the transistor 3 is applied to the transistor 3 from the voltage control circuit 9. In the bypass mode, such a bias voltage that the transistor 3 becomes the OFF state so as not to amplify the signal is applied to the transistor 3 from the voltage control circuit 9. In this manner, the amplifying mode and the bypass mode are switched.

The second-harmonic reflection circuit 16 connected to the bypass path has such impedance that is open at the fundamental frequency and is almost short-circuited at the second harmonic. Second-harmonic impedance as seen from the transistor 3 to the output side is determined by a path connecting to the second-harmonic reflection circuit 16 via the microstrip line 15. A reflection phase angle of the second-harmonic impedance as seen from the transistor 3 to the output side is determined by the length of the microstrip line 15. In other words, the microstrip line 15 constitutes part of the bypass path and functions also as a line for adjusting the second-harmonic reflection phase angle. In this case, the second-harmonic impedance as seen from the transistor 3 to the output side is set to an almost short-circuited state, for example, so that the reflection phase angle (that is, an impedance reflection phase angle of the second harmonic of a transmission signal as seen from the second node 12 to the bypass path (including the second-harmonic reflection circuit 16)) falls within 180±45 deg.

On the other hand, fundamental-frequency impedance as seen from the transistor 3 to the output side is determined by the matching circuit 14. The fundamental-frequency impedance as seen from the third node 13 to the second-harmonic reflection circuit 16 is open, and hence fundamental-frequency impedance in the path connecting from the transistor 3 to the second-harmonic reflection circuit 16 via the microstrip line 15 is almost open when the length of the microstrip line 15 is sufficiently shorter than the wavelength. Thus, this fundamental-frequency impedance does not affect the fundamental-frequency impedance as seen from the transistor 3 to the output side.

Therefore, in this amplifier, only the reflection phase angle of the second-harmonic impedance can be adjusted by the length of the microstrip line 15 without affecting the fundamental-frequency impedance as seen from the transistor 3 to the output side. Thus, the matching for the fundamental-frequency impedance and the matching for the second-harmonic impedance can be optimized independently, thus improving the efficiency of the amplifier.

Note that, in this embodiment, a heterojunction bipolar transistor may be used as the transistor 3. Further, the fundamental-frequency impedance of the second-harmonic reflection circuit 16 may not be open (the reflection phase angle is 0 deg), but the reflection phase angle (that is, an impedance reflection phase angle at the frequency of the transmission signal as seen from the third node 13 to the second-harmonic reflection circuit 16 side) may fall within ±30 deg.

### Second Embodiment

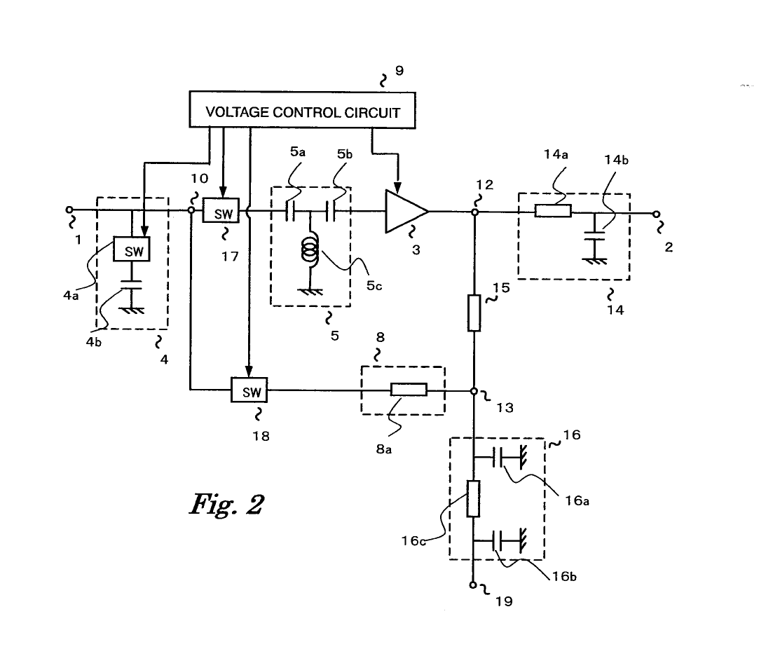

FIG. 2 illustrates a configuration diagram of an output mode switching amplifier according to a second embodiment of the present invention. A first switch 17 and a second switch 18 whose ON/OFF is switched by control of, for example, a bias voltage from the voltage control circuit 9 are inserted between the first node 10 and the matching circuit 5 and between the first node 10 and the matching circuit 8, respectively. FIG. 2 also illustrates specific examples of the configurations of the second-harmonic reflection circuit 16 and each of the matching circuits 4, 5, 8, and 14.

In the amplifier of FIG. 2, an input signal is amplified by the transistor 3 when the output is high (amplifying mode), but a signal is output while bypassing the transistor 3 by the bypass path when the output is low (bypass mode). In the amplifying mode, by the voltage control circuit 9, such a bias voltage that the signal can be amplified by the transistor 3 is set to the transistor 3, and such bias voltages that the switch 17 becomes ON (pass) and the switch 18 becomes OFF (open) are set to the respective switches. In the bypass mode, on the other hand, such a bias voltage that the transistor 3 becomes the OFF state so as not to amplify the signal is set, and such bias voltages that the switch 17 becomes OFF and the switch 18 becomes ON are set to the respective switches.

The matching circuit 4 includes a switch 4a and a capacitor 4b connected between a signal path (signal line) and the ground. The switch 4a is switched by the bias voltage control of the voltage control circuit 9 so that the matching state can be maintained both in the amplifying mode and the bypass mode.

The matching circuit 14 includes a line 14a (such as a microstrip line) connected in series to the signal path and a capacitor 14b connected in parallel to the signal path. The matching circuit 14 performs matching of the fundamental-frequency impedance on the output side.

The second-harmonic reflection circuit 16 includes a plurality of parallel capacitors 16a and 16b and a series line 16c (such as a microstrip line), and is shared with a bias circuit. A power supply terminal 19 is connected ahead of the second-harmonic reflection circuit 16. The second-harmonic reflection circuit 16 creates the conditions that the impedance as seen from the third node 13 to the second-harmonic reflection circuit 16 is open at the fundamental frequency and that an amplitude component of a reflection coefficient is close to 1 at the second harmonic.

The matching circuit 5 includes capacitors 5a and 5b connected in series to the signal line and an inductor 5c connected in parallel to the signal line. The matching circuit 8 includes a high-impedance line 8a connected in series to the bypass path. The matching circuit 5 acts as a high-pass filter, and hence the characteristics in which the phase is advanced with respect to the frequency are obtained. The matching circuit 8 acts as a low-pass filter, and hence the characteristics in which the phase is delayed with respect to the frequency are obtained.

Therefore, in this embodiment, the difference between a pass phase in a path reaching the second node 12 from the first node 10 via the transistor 5 in the amplifying mode and a pass phase in a path reaching the node 12 from the first node 10 via the bypass path in the bypass mode can be set to be small, such as within ±30 deg.

Second-harmonic impedance as seen from the transistor 3 to the output side is determined by a path connecting to the second-harmonic reflection circuit 16 via the microstrip line 15, and a reflection phase angle of the second-harmonic impedance as seen from the transistor 3 to the output side is determined by the length of the microstrip line 15. In other words, the microstrip line 15 constitutes part of the bypass path and functions also as a line for adjusting the second-harmonic reflection phase angle. In this case, the second-harmonic impedance as seen from the transistor 3 to the output side is set to an almost short-circuited state, for example, so that the reflection phase angle (that is, an impedance reflection phase angle of the second harmonic of a transmission signal as seen from the second node 12 to the bypass path (including the second-harmonic reflection circuit 16)) may fall within 180±45 deg.

On the other hand, fundamental-frequency impedance as seen from the transistor 3 to the output side is determined by the matching circuit 14. The fundamental-frequency impedance as seen from the third node 13 to the second-harmonic reflection circuit 16 is open, and hence fundamental-frequency impedance in the path connecting from the transistor 3 to the second-harmonic reflection circuit 16 via the microstrip line 15 is almost open when the length of the microstrip line 15 is sufficiently shorter than the wavelength. Thus, this fundamental-frequency impedance does not affect the fundamental-frequency impedance as seen from the transistor 3 to the output side.

Therefore, in this amplifier, only the reflection phase angle of the second-harmonic impedance can be adjusted by the length of the microstrip line 15 without affecting the fundamental-frequency impedance as seen from the transistor 3 to the output side. Thus, the matching for the fundamental-frequency impedance and the matching for the second-harmonic impedance can be optimized independently, thus improving the efficiency of the amplifier.

Note that, in this embodiment, a heterojunction bipolar transistor may be used as the transistor 3. In addition, the fundamental-frequency impedance of the second-harmonic reflection circuit 16 may not be open (the reflection phase angle is 0 deg), but the reflection phase angle (that is, an impedance reflection phase angle at the frequency of the transmission signal as seen from the third node 13 to the second-harmonic reflection circuit 16 side) may fall within ±30 deg.

### INDUSTRIAL APPLICABILITY

The output mode switching amplifier according to the present invention is applicable to amplifiers in various fields, and provides considerable effects.

### REFERENCE SIGNS LIST

1 RF input terminal, 2 RF output terminal, 3 transistor (for signal amplification), 4, 5, 8, 14 matching circuit, 4a, 17 18 switch, 4b, 5a, 5b, 14b, 16a, 16b capacitor, 5c inductor, 8a high-impedance line, 9 voltage control circuit, 10 first node, 12 second node, 13 third node, 14a, 16c line, 15 microstrip line, 16 second-harmonic reflection circuit, 19 power supply terminal

1-7. (canceled)

8. An output mode switching amplifier, comprising:
a transistor for signal amplification connected between a first node on an input side and a second node on an output side;
a bypass path for bypassing the transistor between the first node and the second node;
a voltage control circuit for switching whether to apply a bias voltage to the transistor so that a transmission signal is amplified by the transistor or to output a transmission signal via the bypass path without amplifying the transmission signal by the transistor;
a second-harmonic reflection circuit connected to the bypass path, for reflecting a second harmonic of the transmission signal, and
a microstrip line inserted and connected in the bypass path between the second node and the second-harmonic reflection circuit.

9. The output mode switching amplifier according to claim 8, further comprising:
a first switch connected between the first node and the transistor; and
a second switch connected between the first node and the bypass path,
wherein the voltage control circuit further switches whether to input the transmission signal to the transistor or input the transmission signal to the bypass path, by applying bias voltages to the first switch and the second switch.

10. The output mode switching amplifier according to claim 8, further comprising:
a first matching circuit inserted and connected between the second node and an output terminal of the output mode switching amplifier.

11. The output mode switching amplifier according to claim 9, further comprising:
a first matching circuit inserted and connected between the second node and an output terminal of the output mode switching amplifier.

12. The output mode switching amplifier according to claim 8, wherein an impedance reflection phase angle at a frequency of the transmission signal as seen from a third node, which is a connection point between the bypass path and the second-harmonic reflection circuit, to the second-harmonic reflection circuit side falls within ±30 deg.

13. The output mode switching amplifier according to claim 9, wherein an impedance reflection phase angle at a frequency of the transmission signal as seen from a third node, which is a connection point between the bypass path and the second-harmonic reflection circuit, to the second-harmonic reflection circuit side falls within ±30 deg.

14. The output mode switching amplifier according to claim 8, wherein an impedance reflection phase angle of the second harmonic of the transmission signal as seen from the second node to the bypass path falls within 180±45 deg.

15. The output mode switching amplifier according to claim 9, wherein an impedance reflection phase angle of the second harmonic of the transmission signal as seen from the second node to the bypass path falls within 180±45 deg.

16. The output mode switching amplifier according to claim 8, further comprising a second matching circuit connected between the first node and the transistor, the second matching circuit including capacitors connected in series to a signal line and an inductor connected in parallel to the signal line,
wherein a first path reaching the second node from the first node via the second matching circuit and the transistor and a second path reaching the second node from the first node via the bypass path have a pass phase difference of within 30 deg.

17. The output mode switching amplifier according to claim 9, further comprising a second matching circuit connected between the first node and the transistor, the second matching circuit including capacitors connected in series to a signal line and an inductor connected in parallel to the signal line,
wherein a first path reaching the second node from the first node via the second matching circuit and the transistor and a second path reaching the second node from the first node via the bypass path have a pass phase difference of within 30 deg.

18. The output mode switching amplifier according to claim 8, wherein the transistor comprises a heterojunction bipolar transistor.

19. The output mode switching amplifier according to claim 9, wherein the transistor comprises a heterojunction bipolar transistor.

20. The output mode switching amplifier according to claim 10, wherein the transistor comprises a heterojunction bipolar transistor.

21. The output mode switching amplifier according to claim 11, wherein the transistor comprises a heterojunction bipolar transistor.

22. The output mode switching amplifier according to claim 12, wherein the transistor comprises a heterojunction bipolar transistor.

23. The output mode switching amplifier according to claim 13, wherein the transistor comprises a heterojunction bipolar transistor.

24. The output mode switching amplifier according to claim 14, wherein the transistor comprises a heterojunction bipolar transistor.

25. The output mode switching amplifier according to claim 15, wherein the transistor comprises a heterojunction bipolar transistor.

26. The output mode switching amplifier according to claim 16, wherein the transistor comprises a heterojunction bipolar transistor.

27. The output mode switching amplifier according to claim 17, wherein the transistor comprises a heterojunction bipolar transistor.
